(19) United States
(12) Patent Application Publication
(10) Pub. No.: US 2024/0347593 A1
(43) Pub. Date: Oct. 17, 2024

(54) NANOWIRE/NANOSHEET DEVICE WITH REPLACED SPACER, METHOD OF MANUFACTURING NANOWIRE/NANOSHEET DEVICE WITH REPLACED SPACER, AND ELECTRONIC APPARATUS

(71) Applicant: INSTITUTE OF MICROELECTRONICS, CHINESE ACADEMY OF SCIENCES, Beijing (CN)

(72) Inventor: Huilong Zhu, Poughkeepsie, NY (US)

(21) Appl. No.: 18/292,584

(22) PCT Filed: Feb. 17, 2022
(86) PCT No.: PCT/CN2022/076616

§ 371 Date: Jan. 26, 2024

(30) Foreign Application Priority Data
Dec. 13, 2021 (CN) 202111521279.4

(51) Int. Cl. H01L 29/06; H01L 29/08; H01L 29/423; H01L 29/66; H01L 29/775; H01L 29/786

(52) U.S. Cl. CPC H01L 29/0673; H01L 29/0847; H01L 29/42392; H01L 29/66439; H01L 29/66545; H01L 29/6656; H01L 29/775; H01L 29/78696

(57) ABSTRACT

A nanowire/nanosheet device and a method of manufacturing the same, and an electronic apparatus including the nanowire/nanosheet device. The nanowire/nanosheet device includes: a substrate; a nanowire/nanosheet spaced apart from a surface of the substrate and extending in a first direction; a source/drain layer at opposite ends of the nanowire/nanosheet in the first direction and adjoining the nanowire/nanosheet; a gate stack extending in a second direction intersecting with the first direction to surround the nanowire/nanosheet; and a first spacer on a sidewall of the gate stack, wherein the first spacer includes a continuously extending material layer which has a first part along a surface of the nanowire/nanosheet, a second part along a sidewall of the source/drain layer facing the gate stack, and a third part along a sidewall of the gate stack facing the source/drain layer, and the second part and the third part have a seam or an interface therebetween.

### CROSS REFERENCE TO RELATED APPLICATION(S)

This application claims priority to Chinese Patent Application No. 202111521279.4, filed on Dec. 13, 2021 and entitled “NANOWIRE/NANOSHEET DEVICE WITH SELF-ALIGNED ISOLATION PORTION, METHOD OF MANUFACTURING NANOWIRE/NANOSHEET DEVICE WITH SELF-ALIGNED ISOLATION PORTION, AND ELECTRONIC APPARATUS”, the entire content of which is incorporated herein in its entirety by reference.

### TECHNICAL FIELD

The present disclosure relates to a field of semiconductors, and in particular to a nanowire/nanosheet device with a replaced spacer, a method of manufacturing the nanowire/nanosheet device with the replaced spacer, and an electronic apparatus including the nanowire/nanosheet device.

### BACKGROUND

A nanowire or nanosheet (hereinafter referred to as “nanowire/nanosheet”) device, especially a Gate-All-Around (GAA) metal oxide semiconductor field effect transistor (MOSFET) based on the nanowire/nanosheet, may effectively control a short channel effect and achieve a further miniaturization of the device. In addition, it is desired to achieve an epitaxial growth of a source/drain for, such as increasing the source/drain to facilitate a fabrication of a contact portion to the source/drain, or achieving stress engineering. However, with continuous miniaturization, it is difficult to grow a high-quality source/drain.

### SUMMARY

In view of above, the object of the present disclosure is at least partially to provide a nanowire/nanosheet device with an improved performance, a method of manufacturing the nanowire/nanosheet device, and an electronic apparatus including the nanowire/nanosheet device.

According to an aspect of the present disclosure, a nanowire/nanosheet device is provided, including: a substrate; a nanowire/nanosheet spaced apart from a surface of the substrate and extending in a first direction; a source/drain layer located at opposite ends of the nanowire/nanosheet in the first direction and adjoining the nanowire/nanosheet; a gate stack extending in a second direction intersecting with the first direction to surround the nanowire/nanosheet; and a first spacer provided on a sidewall of the gate stack, wherein the first spacer includes a continuously extending material layer, the continuously extending material layer has a first part along a surface of the nanowire/nanosheet, a second part along a sidewall of the source/drain layer facing the gate stack, and a third part along a sidewall of the gate stack facing the source/drain layer, and the second part and the third part have a seam or an interface therebetween.

According to another aspect of the present disclosure, a method of manufacturing a nanowire/nanosheet device is provided, including: providing, on a substrate, a nanowire/nanosheet spaced apart from a surface of the substrate and extending in a first direction; forming, on the substrate, a dummy gate extending in a second direction intersecting with the first direction and surrounding the nanowire/nanosheet, wherein a first spacer is formed on a sidewall of the dummy gate; growing a source/drain layer on opposite ends of the nanowire/nanosheet in the first direction; replacing the first spacer with a second spacer in a presence of the source/drain layer and at least a part of the dummy gate; and forming a gate stack on an inner side of the second spacer, wherein the second spacer includes a continuously extending material layer, the continuously extending material layer has a first part along a surface of the nanowire/nanosheet, a second part along a sidewall of the source/drain layer facing the gate stack, and a third part along a sidewall of the gate stack facing the source/drain layer, and the second part and the third part have a seam or an interface therebetween.

According to another aspect of the present disclosure, an electronic apparatus is provided, including the nanowire/nanosheet device described above.

According to an embodiment of the present disclosure, a spacer replacement process is adopted. Initially, a first spacer that is conducive to crystal growth may be formed to facilitate the growth of a source/drain layer with a high crystal quality. Subsequently, the first spacer may be replaced with a second spacer. Advantageously, the second spacer may have a low dielectric constant, for example, to reduce a parasitic capacitance.

### BRIEF DESCRIPTION OF THE DRAWINGS

The above and other objects, features, and advantages of the present disclosure will become more clear through following description on embodiments of the present disclosure with reference to accompanying drawings, in which:

FIGS. 1 to 21(b) show schematic diagrams of some stages in a process of manufacturing a nanowire/nanosheet device according to an embodiment of the present disclosure;

FIGS. 22(a) to 23 show schematic diagrams of source/drain growth according to a comparative example;

FIGS. 24(a) to 31 show schematic diagrams of some stages in a process of manufacturing a nanowire/nanosheet device according to another embodiment of the present disclosure;

FIG. 32 shows a schematic diagram of a nanowire/nanosheet device according to another embodiment of the present disclosure, wherein

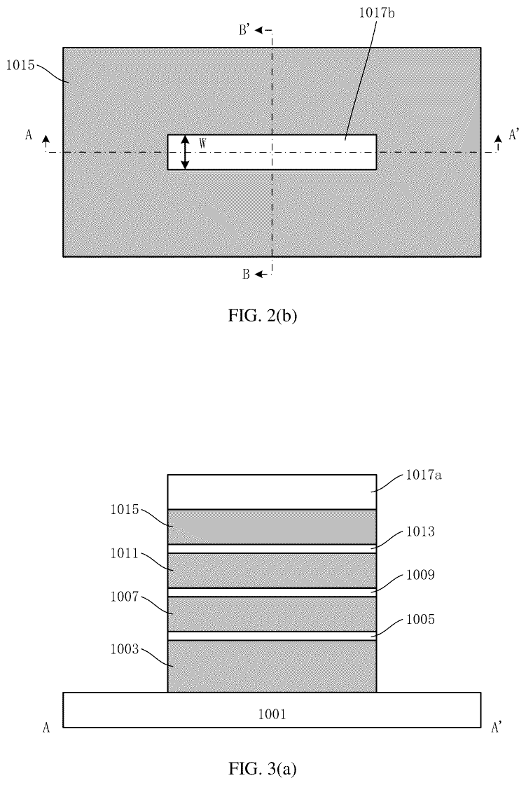

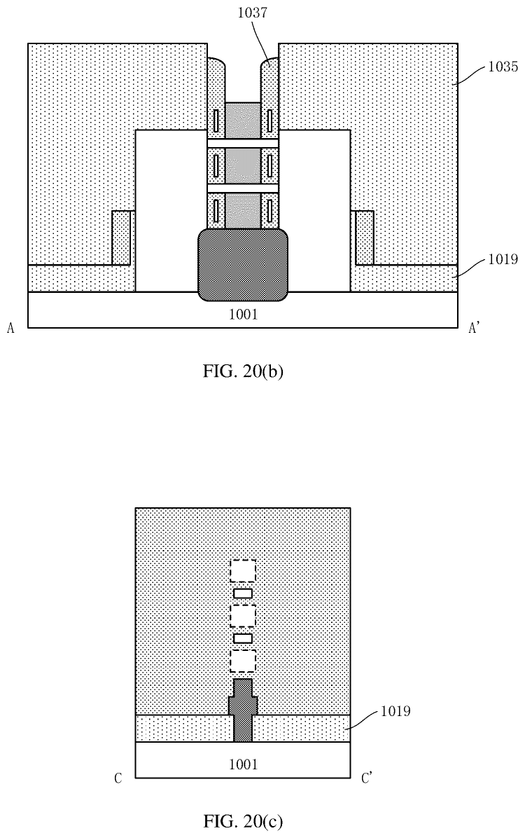

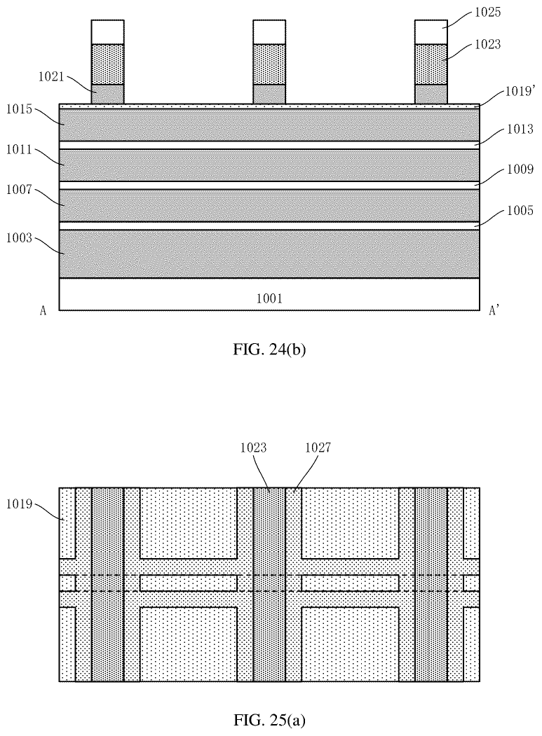

FIGS. 2(a), 2(b), 5(a), 6(a), 16(a), 17(a), 20(a), 24(a) and 25(a) are top views, wherein FIG. 2(a) shows positions of line AA′ and line BB′, FIG. 20(a) shows a position of line CC′, and FIG. 24(a) shows positions of line DD′ and line EE′,

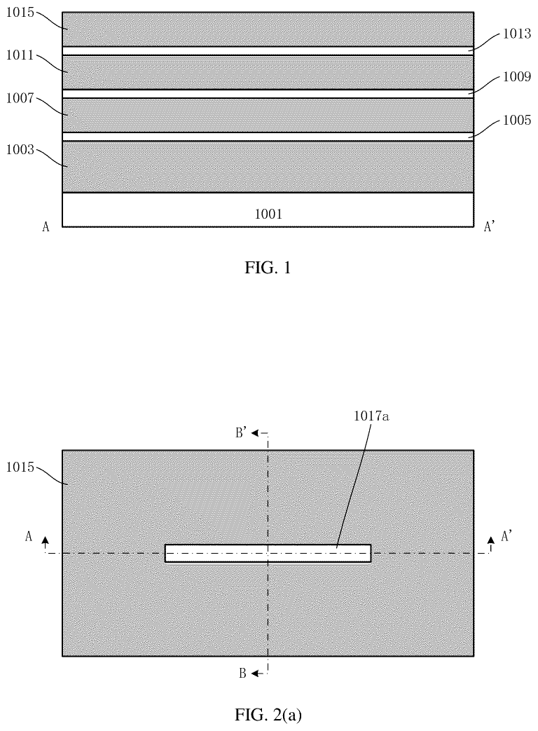

FIGS. 1, 3(a), 4(a), 5(b), 6(b), 7, 8, 9(a), 10(a), 10(b), 11(a), 12(a), 13(a), 14(a), 15(a), 16(b), 17(b), 18, 19, 20(b), 21(a), 22(a), 23, 24(b), 25(b), 26(a), and 27 to 32 are cross-sectional views taken along line AA′,

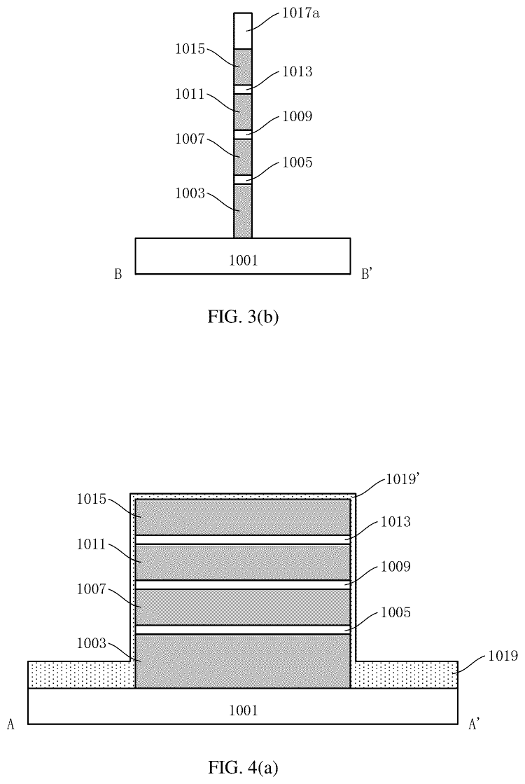

FIGS. 3(b), 4(b), 9(b), 11(b), 12(b), 13(b), 14(b), 15(b), 16(c), 21(b) and 26(b) are cross-sectional views taken along line BB′,

FIG. 20(c) is a cross-sectional view taken along line CC′,

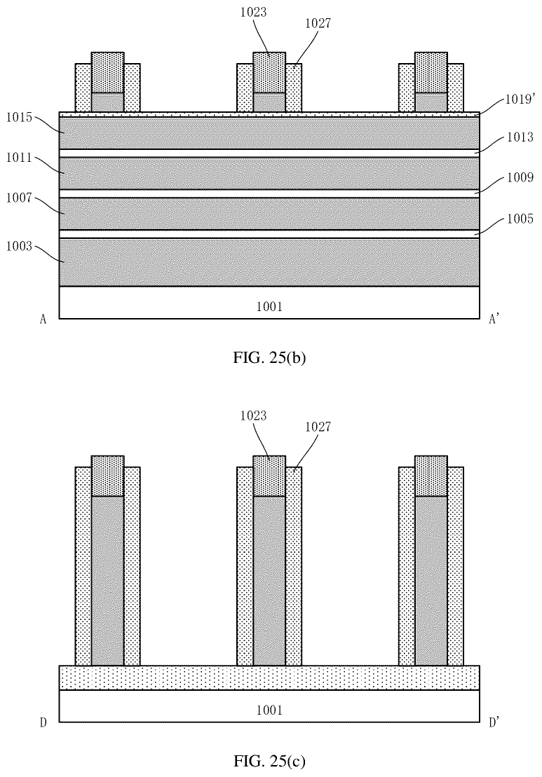

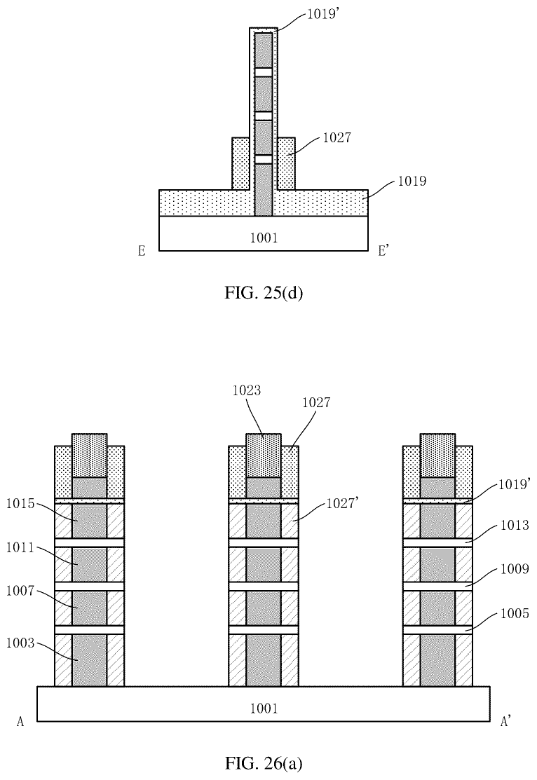

FIG. 25(c) is a cross-sectional view taken along line DD′,

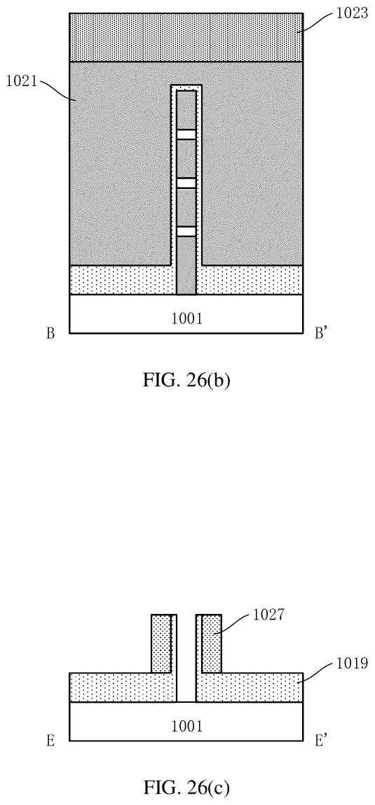

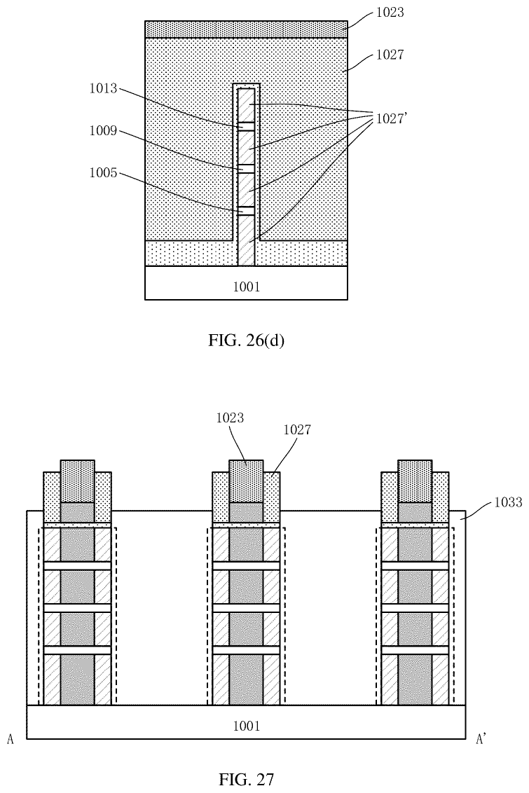

FIGS. 25(d) and 26(c) are cross-sectional views taken along line EE′,

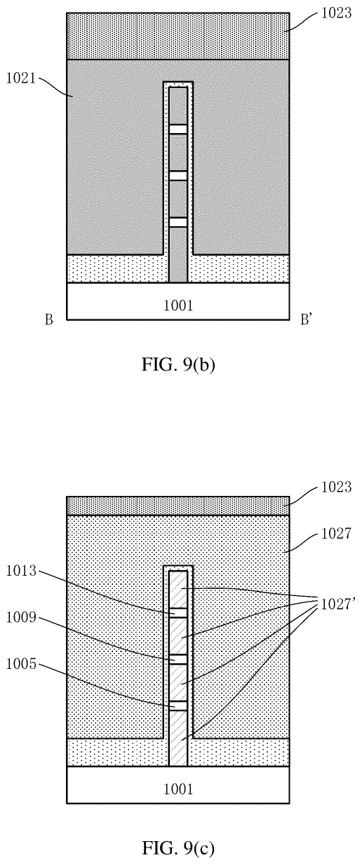

FIGS. 9(c), 22(b) and 26(d) are cross-sectional views obtained along a sidewall of a spacer.

### DETAILED DESCRIPTION OF EMBODIMENTS

Hereinafter, embodiments of the present disclosure will be described with reference to accompanying drawings. However, it should be understood that these descriptions are illustrative and not intended to limit the scope of the present disclosure. Further, in the following, descriptions for known structures and technologies are omitted to avoid obscuring the concept of the present disclosure unnecessarily.

Various structures according to the embodiments of the present disclosure are shown in the accompanying drawings. However, they are not drawn to scale, and some features may be enlarged while some features may be omitted for sake of clarity. Shapes, relative sizes and positions of regions and layers shown in the drawings are only illustrative, and deviations may occur due to manufacture tolerances or technique limitations in practice. In addition, those skilled in the art may devise regions/layers of other different shapes, sizes, and relative positions as desired in practice. In the context of the present disclosure, when a layer/element is recited as being “on” a further layer/element, the layer/element may be provided directly on the further layer/element, or otherwise there may be an intervening layer/element interposed therebetween. Further, if a layer/element is “on” a further layer/element in an orientation, then the layer/element may be “under” the further layer/element when the orientation is turned.

According to an embodiment of the present disclosure, a nanowire/nanosheet device is provided. Specifically, the device may include one or more nanowires or nanosheets to serve as a channel. The nanowire/nanosheet may be suspended relative to a substrate and may extend substantially parallel to a surface of the substrate. The nanowires/nanosheets are aligned with each other in a vertical direction (e.g., in a direction substantially perpendicular to the surface of the substrate). The nanowire/nanosheet may extend in a first direction, and opposite ends of the nanowire/nanosheet in the first direction may be connected to a source/drain layer. The source/drain layer may include a semiconductor material different from the nanowire/nanosheet to achieve stress engineering. In addition, a gate stack may extend in a second direction that intersects with (such as perpendicular to) the first direction to intersect with each nanowire/nanosheet, and thus may surround a periphery of each nanowire/nanosheet, so as to form a Gate-All-Around (GAA) structure.

A spacer may be formed on a sidewall of the gate stack. The spacer may isolate the gate stack from the source/drain layer. As described below, the spacer may be formed through a spacer replacement process. In the spacer replacement process, a limited space may be filled with at least a part (referred to as a “first part”) of the spacer, specifically, a part of the spacer that overlaps the nanowire/nanosheet in the vertical direction. The filling of the limited space may lead to a seam (such as an air gap) or an interface or a surface. As a result, the part of the spacer in the limited space may be O-shaped or U-shaped. For example, the first part of the spacer may include a continuously extending material layer, which has a first part along a surface of the nanowire/nanosheet, a second part along a sidewall of the source/drain layer facing the gate stack, and a third part along a sidewall of the gate stack facing the source/drain layer (there may further be a fourth part opposite to the first part and connecting the second part and the third part). The second part and the third part have a seam or an interface therebetween. Due to such seam, the spacer may have a reduced dielectric constant and thus the device performance is improved.

An isolation portion may be provided between the gate stack and the substrate. The isolation portion may be self-aligned with the gate stack and may be substantially aligned with the nanowire/nanosheet in the vertical direction.

Such semiconductor device may be manufactured as follows. A nanowire/nanosheet, which is spaced apart from a surface of the substrate and extends in the first direction, may be provided on the substrate. A dummy gate, which extends in a second direction intersecting with (such as perpendicular to) the first direction, may be formed to surround the nanowire/nanosheet. A first spacer may be formed on a sidewall of the dummy gate. After the source/drain layer is grown at opposite ends of the nanowire/nanosheet in the first direction, the first spacer may be replaced with a second spacer (i.e., the spacer replacement process). In the spacer replacement process, there is a limited space defined by (at least a part of) the dummy gate, the source/drain layer, and each nanowire/nanosheet. Therefore, the second spacer may have the seam or the interface or the surface as described above due to such limited space.

The first spacer is conducive to a growth of the source/drain layer. For example, the first spacer may have a crystal structure substantially identical to the nanowire/nanosheet in at least a region of the first spacer adjacent to the nanowire/nanosheet. Accordingly, the source/drain layer may be grown by using the ends of the nanowire/nanosheet in the first direction and the region of the first spacer as seeds. This helps to reduce defects in the source/drain layer and thus improve the crystal quality of the source/drain layer.

An isolation portion defining layer may be provided on the substrate. The nanowire/nanosheet may be provided on the isolation portion defining layer. The isolation portion defining layer may be patterned in a shape self-aligned with the nanowire/nanosheet, which may be achieved by etching the isolation portion defining layer using the nanowire/nanosheet (or the (hard) mask used to form the nanowire/nanosheet) as a mask. Afterwards, a self-aligned isolation portion may be formed by replacing the isolation portion defining layer with a dielectric material.

In order to providing the nanowire/nanosheet, a stack, in which one or more gate defining layers and one or more nanowire/nanosheet defining layers are arranged alternatively, may be formed on the isolation portion defining layer. The stack may be patterned as a preparatory nanowire/nanosheet extending in the first direction. A length of the preparatory nanowire/nanosheet in the first direction may be greater than a length of a final nanowire/nanosheet to be formed in the first direction, so as to subsequently form a nanowire/nanosheet self-aligned with the dummy gate. In this patterning process, the isolation portion defining layer may also be patterned. Accordingly, the isolation portion defining layer may be self-aligned with the preparatory nanowire/nanosheet. At this point, the gate defining layer is also in a shape of nanowire/nanosheet. To form the GAA, a further gate defining layer may be formed and patterned as a strip extending in the second direction. A first sub-spacer may be formed on a sidewall of the strip-shaped further gate defining layer. The first sub-spacer may also be formed on the sidewall of the stack. The strip-shaped further gate defining layer and the first sub-spacer may be used as masks to pattern the preparatory nanowire/nanosheet below. Accordingly, the strip-shaped further gate defining layer forms the dummy gate extending in the second direction along with other gate defining layers. The nanowire/nanosheet defining layer is patterned as a nanowire/nanosheet self-aligned with the dummy gate, and the nanowire/nanosheet is surrounded by the dummy gate. In this patterning process, the isolation portion defining layer may also be patterned. Accordingly, the isolation portion defining layer may be self-aligned with the nanowire/nanosheet.

In addition, the gate defining layer may be selectively etched so that the sidewall of the gate defining layer is inward recessed relative to the sidewall of the nanowire/nanosheet, and a second sub-spacer is formed in the recess formed thereby. Accordingly, the second sub-spacer may be self-aligned with the gate defining layer. The first and second sub-spacers may form the first spacer described above. The second sub-spacer may facilitate the growth of the source/drain layer.

In the spacer replacement process, the further gate defining layer may be removed to expose the first sub-spacer. The first sub-spacer may be removed to expose an end of the second sub-spacer in the second direction. The second sub-spacer may be removed, and a second spacer may be formed. A space (the limited space) where the second sub-spacer is originally located may be filled with the second spacer.

The present disclosure may be presented in various forms, some examples of which will be described below. In the following description, a selection of various materials is involved. In the selection of materials, in addition to a function of the material (for example, a semiconductor material may be used to form an active region, a dielectric material may be used to form an electrical isolation), the etching selectivity is also considered. In the following description, the required etching selectivity may or may not be indicated. It should be clear to those skilled in the art that when etching a material layer is described below, if it is not described or shown that other layers are also etched, then the etching may be selective, and the material layer may have an etching selectivity relative to other layers exposed to the same etching recipe.

FIGS. 1 to 21(b) show schematic diagrams of some stages in a process of manufacturing a nanowire/nanosheet device according to an embodiment of the present disclosure.

As shown in FIG. 1, a substrate 1001 is provided. The substrate 1001 may be a substrate in various forms, including but not limited to, a bulk semiconductor material substrate such as a bulk Si substrate, a Semiconductor On Insulator (SOI) substrate, a compound semiconductor substrate such as an SiGe substrate, or the like. Hereinafter, the bulk Si substrate will be described by way of example for the convenience of description. Here, a silicon wafer is provided as the substrate 1001.

An isolation portion defining layer 1003 may be formed on the substrate 100 for defining a position of an isolation portion to be formed subsequently. An etch stop layer 1005 may be formed on the isolation portion defining layer 1003. The etch stop layer 1005 may define a stop position when etching the isolation portion defining layer 1003 subsequently, especially there is no etching selectivity or there is a low etching selectivity between the isolation portion defining layer 1003 and a gate defining layer (such as 1007) formed subsequently. Alternatively, the etch stop layer 1005 may be omitted in a case where there is an etching selectivity between the isolation portion defining layer 1003 and the gate defining layer formed subsequently.

A stack of alternately arranged gate defining layers 1007, 1011 and 1015 and nanowire/nanosheet defining layers 1009 and 1013 may be formed on the etch stop layer 1005. The gate defining layers 1007, 1011 and 1015 may define a position of the gate stack to be formed subsequently. The nanowire/nanosheet defining layers 1009 and 1013 may define a position of the nanowire/nanosheet to be formed subsequently. In this stack, the top layer may be the gate defining layer 1015, so that each nanowire/nanosheet defining layer 1009 or 1013 is covered by the gate defining layers above and below, so as to form the GAA configuration subsequently. In this example, two nanowire/nanosheet defining layers 1009 and 1013 are formed, and thus two nanowires/nanosheets are formed in the resultant device. However, the present disclosure is not limited to this. The number of nanowire/nanosheet defining layers to be formed and the corresponding number of gate defining layers to be formed may be determined according to the final number of nanowires/nanosheets to be formed (which may be one or more).

The isolation portion defining layer 1003, the etch stop layer 1005, the gate defining layers 1007, 1011 and 1015, as well as the nanowire/nanosheet defining layers 1009 and 1013 may be semiconductor layers formed on the substrate 1001 by, for example, epitaxial growth. Therefore, the nanowire/nanosheet defining layers 1009 and 1013 may have good crystal quality and may be single crystal structures, so as to subsequently provide single crystal nanowires/nanosheets to serve as channels. Adjacent semiconductor layers among these semiconductor layers may have etching selectivity relative to each other, so that they may be subsequently processed differently. For example, the etch stop layer 1005 and the nanowire/nanosheet defining layers 1009 and 1013 may include Si, while the isolation portion defining layer 1003 and the gate defining layers 1007, 1011, and 1015 may include SiGe (an atomic percentage of Ge may be in a range of about 10% to 40%, and may gradually change to reduce defects). Each semiconductor layer may have a substantially uniform thickness, so as to extend substantially parallel to the surface of the substrate 1001. For example, a thickness of the isolation portion defining layer 1003 may be in a range of about 30 nm to 80 nm, a thickness of the etch stop layer 1005 may be in a range of about 3 nm to 15 nm, a thickness of each of the gate defining layers 1007, 1011, and 1015 may be in a range of about 20 nm to 40 nm, and a thickness of each of the nanowire/nanosheet defining layers 1009 and 1013 may be in a range of about 5 nm to 15 nm.

Next, the nanowire/nanosheet may be patterned. For example, as shown in FIG. 2(a) or 2(b), a photoresist 1017a or 1017b may be formed on the stack described above and patterned in a form of nanowire (FIG. 2(a)) or nanosheet (FIG. 2(b)) through photolithography. In a case of the nanosheet, a width W of the nanosheet may determine a device width that provides a current. In the following descriptions, a case of the nanowire is mainly used as an example, but these descriptions also apply to the case of the nanosheet. Then, as shown in FIGS. 3(a) and 3(b), by using the photoresist 1017a or 1017 as an etching mask, various layers on the substrate 1001 may be selectively etched sequentially by reactive ion etching (RIE) in the vertical direction, and the etching may be stopped at the substrate 1001. In this way, various layers on the substrate 1001 are patterned as a preparatory nanowire or nanosheet corresponding to the photoresist 1017a or 1017b. Here, a length of the preparatory nanowire/nanosheet (a longitudinal dimension, i.e., a length in the horizontal direction within the plane of the paper under the orientation in FIG. 3(a)) may be greater than a length of the nanowire/nanosheet to be formed to serve as the channel, so as to subsequently obtain the nanowire/nanosheet self-aligned with the dummy gate (gate stack) to serve as the channel. Afterwards, the photoresist 1017a or 1017b may be removed.

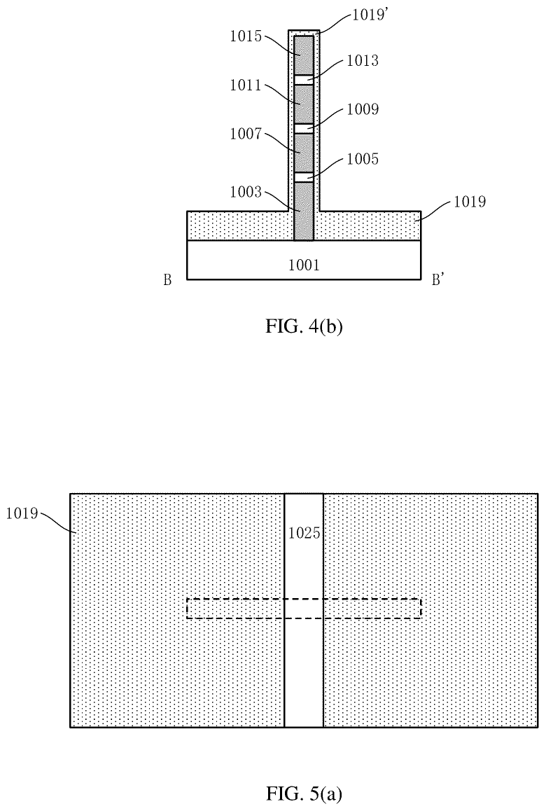

For the purpose of electrical isolation, as shown in FIGS. 4(a) and 4(b), an isolation portion 1019 may be formed on the substrate 1001, such as shallow trench isolation (STI). For example, an STI 1019 may be formed by depositing an oxide (such as a silicon oxide) on the substrate, performing a planarization processing such as chemical mechanical polishing (CMP) on the deposited oxide, and etching back the planarized oxide through wet etching or vapor or dry etching. In addition, a thin etch stop layer 1019′ (for example, with a thickness in a range of about 1 nm to 5 nm) may be formed by deposition on a surface of the stack of semiconductor layers patterned in the form of nanowire/nanosheet on the substrate 1001. Here, the etch stop layer 1019′ may also include an oxide and thus is shown as a thin layer integrated with the STI 1019.

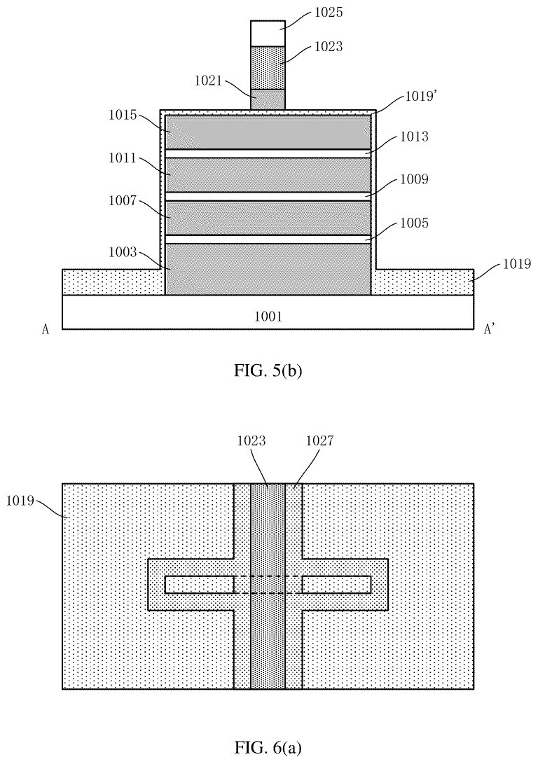

As described above, the gate defining layers 1007, 1011 and 1015 are located on the upper and lower sides of the nanowire/nanosheet defining layers 1009 and 1013. To form the GAA, a further gate defining layer may be formed on the left and right sides under an orientation shown in FIG. 4(b). For example, as shown in FIGS. 5(a) and 5(b), a gate defining layer 1021 may be formed on the STI 1019 and the etch stop layer 1019′. For example, the gate defining layer 1021 may be formed by depositing a material that is substantially the same as or similar to the previous gate defining layers 1007, 1011 and 1015 (thereby having substantially the same or similar etching selectivity for processing together), and performing a planarization processing such as CMP on the deposited material. In this example, the gate defining layer 1021 may include SiGe with a Ge atom percentage that is substantially the same as or similar to the gate defining layers 1007, 1011 and 1015.

A hard mask layer 1023 may be formed on the gate defining layer 1021 by, for example, deposition to facilitate patterning. For example, the hard mask layer 1023 may include silicon carbide with a thickness in a range of about 100 nm to 250 nm.

The gate defining layer 1021 (as well as 1007, 1011 and 1015) may be patterned as a dummy gate that extends along a direction (which may be referred to as a “second direction”, for example, the vertical direction within the plane of the paper in FIG. 5(a), and the direction perpendicular to the plane of the paper in FIG. 5(b)) that intersects with such as perpendicular to an extension direction (which may be referred to as the “first direction”, for example, the horizontal direction within the plane of the paper in FIGS. 5(a) and 5(b)) of the preparatory nanowire/nanosheet. For example, a photoresist 1025 may be formed on the hard mask layer 1023 and patterned as a strip extending in the second direction through photolithography. Then, by using the photoresist 1025 as an etching mask, selectively etching may be performed on the hard mask layer 1023 and the gate defining layer 1021 by RIE. The etching may be stopped at the etch stop layer 1019′. Afterwards, the photoresist 1025 may be removed.

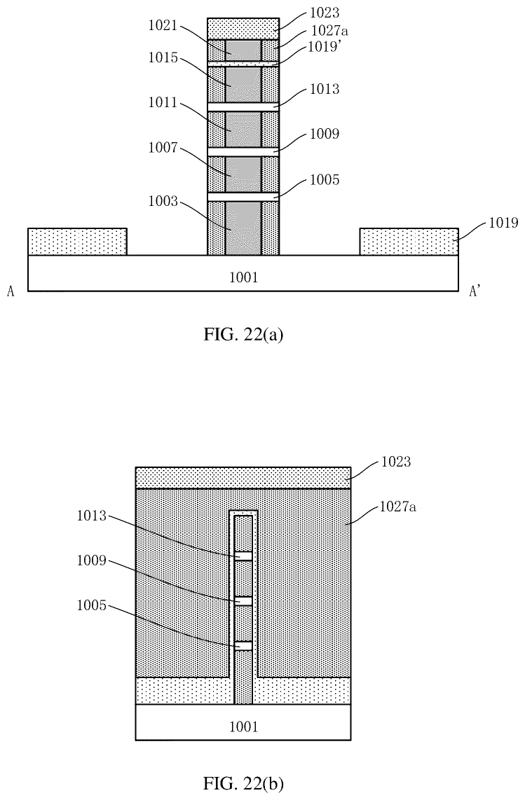

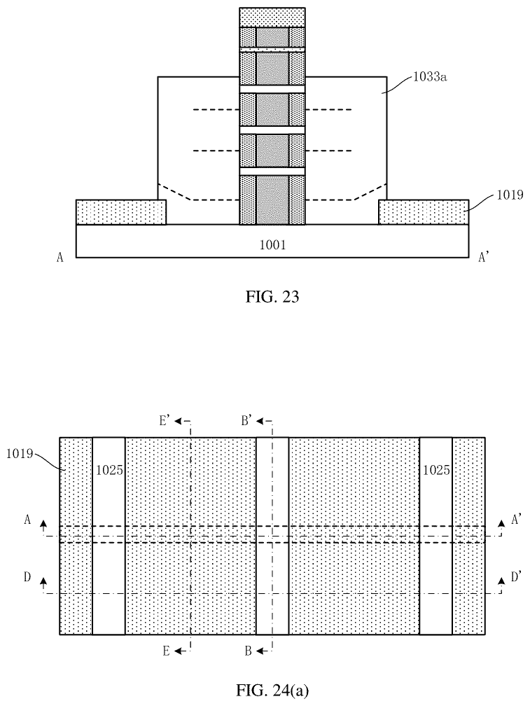

In related art, after patterning the gate defining layer 1021, the photoresist 1025 and the hard mask layer 1023 may also be used as etching masks to pattern the gate defining layers 1007, 1011 and 1015 below, so that the gate defining layers 1007, 1011, 1015, and 1021 form the dummy gate together (and thus the nanowire/nanosheet defining layers 1009 and 1013 may also be similarly patterned to form nanowires/nanosheets, and the etch stop layer 1005 and the isolation portion defining layer 1003 may also be similarly patterned). By selective etching, the gate defining layers 1007, 1011, 1015 and 1021 (as well as the isolation portion defining layer 1003) may be relatively recessed in the lateral direction, and a spacer 1027a of dielectric that is self-aligned with two sides of the dummy gate may be formed in the recess to define a space for forming the gate stack, as shown in FIGS. 22(a) and 22(b). However, this may cause problems during subsequent growth of the source/drain layer. As shown in FIG. 22(b), the spacer 1027a extends continuously with some openings. The nanowires/nanosheets 1009 and 1013 (and the etch stop layer 1005) may be exposed through such openings. Due to the presence of the spacer 1027a of dielectric (usually not a good crystal growth seed), nanowires/nanosheets 1009 and 1013 (as well as the etch stop layer 1005 and the substrate 1001) that serve as crystal growth seeds form some discrete growth points. Accordingly, there may be many defects, such as dislocations or interfaces, in the grown source/drain layer (see 1033a in FIG. 23). For example, crystals grown from different seeds (exposed sidewalls of the nanowires/nanosheets 1009 and 1013, the exposed sidewall of the etch stop layer 1005, and the exposed surface of the substrate 1001) may converge with each other to form an interface, as shown by the dashed lines in FIG. 23.

According to an embodiment of the present disclosure, before growing the source/drain layer, at least a part of the formed spacer may have the same or substantially the same crystal structure as the nanowire/nanosheet defining layers 1009 and 1013, thereby facilitating crystal growth. Such part of the spacer may form a substantially consistent and continuous crystal growth surface with at least a part of the sidewalls of the nanowire/nanosheet defining layers 1009 and 1013 (as well as the sidewall of the etch stop layer 1005, where growth also occurs).

According to an embodiment of the present disclosure, the spacer may be formed in stages. The advantages of forming the spacer in stages will be described in detail below in conjunction with subsequent processes. The present disclosure is not limited to this. The spacer may also be formed at one time as described in conjunction with FIGS. 22(a) and 22(b). The difference is that the spacer may have the same or substantially the same crystal structure as the nanowire/nanosheet defining layers 1009 and 1013, which is conducive to crystal growth.

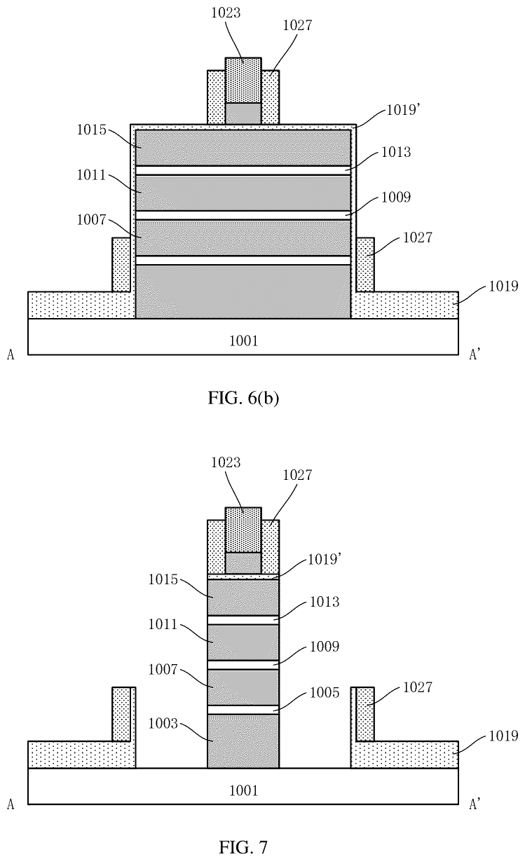

For example, as shown in FIGS. 6(a) and 6(b), a first sub-spacer 1027 may be formed on the sidewall of the gate defining layer 1021 that has been patterned as the strip extending in the second direction. There are various ways to form the spacer in the art. For example, the spacer may be formed by depositing a spacer material layer, such as a nitride (such as a silicon nitride) with a thickness in a range of about 3 nm to 15 nm, in a substantially conformal manner, removing a lateral extension part of the spacer material layer by RIE in the vertical direction, and leaving a vertical extension part of the spacer material layer. Here, the etching depth may be controlled to form the first sub-spacer 1027 on the sidewall of the stack of semiconductor layers, which helps guide the growth of the source/drain layer. As shown in FIGS. 22(a) and 22(b), it is not possible to form the first sub-spacer that guides the growth of the source/drain layer.

After forming the first sub-spacer 1027, similar to FIGS. 22(a) and 22(b), a second sub-spacer may be formed on the sidewalls of the gate defining layers 1007, 1011 and 1015.

For example, as shown in FIG. 7, by using the hard mask layer 1023 and the first sub-spacer 1027 as etching masks, selective etching such as RIE may be performed on the etch stop layer 1019′ and the semiconductor layers of the stack sequentially. The etching may be stopped at the substrate 1001 (or there may be some over-etching). Therefore, the nanowire/nanosheet defining layers 1009 and 1013 are formed as nanowires or nanosheets that may subsequently be used to provide channels (hereinafter, the nanowire/nanosheet defining layers 1009 and 1013 are referred to as the nanowires/nanosheets 1009 and 1013), and are surrounded by the gate defining layers 1007, 1011, 1015 and 1021 (forming the “dummy gate” together). The nanowires/nanosheets 1009 and 1013 may be self-aligned with the dummy gate.

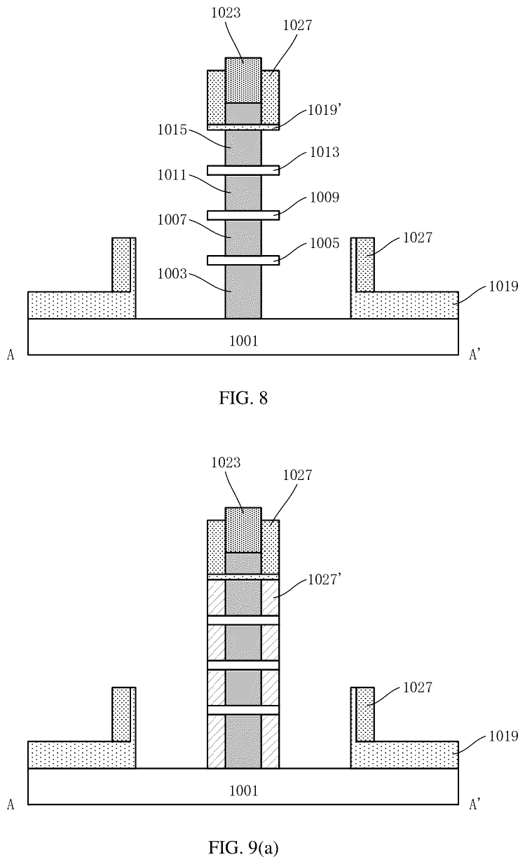

In order to ensure that the gate lengths above and below each of the nanowires/nanosheets 1009 and 1013 are identical with each other, the self-alignment technology may be used to form the second sub-spacer. For example, as shown in FIG. 8, the gate defining layers 1007, 1011 and 1015 (in this example, SiGe) may be selectively etched relative to the nanowires/nanosheets 1009 and 1013 (in this example, Si), so that sidewalls of the gate defining layers 1007, 1011 and 1015 are recessed inward by a certain depth in the lateral direction relative to the sidewalls of the nanowires/nanosheets 1009 and 1013. Preferably, the recess depths of the gate defining layers 1007, 1011 and 1015 are substantially identical, and the recess depths on the left and right sides are substantially identical (and may be substantially equal to the thickness of the first spacer 1027). For example, atomic layer etching (ALE) may be used to achieve good etching control. In this example, the isolation portion defining layer 1003 is also SiGe and may also be recessed by substantially the same depth. Accordingly, the corresponding sidewalls of the etched gate defining layers 1007, 1011 and 1015 (as well as the isolation portion defining layer 1003, and even the gate defining layer 1021) may be substantially coplanar.

The second sub-spacer may be formed in the recess thus formed. As shown in FIGS. 9(a), 9(b) and 9(c), a semiconductor material layer with a thickness sufficient to fill the above-mentioned recess (such as about 3 nm to 15 nm) may be formed by epitaxial growth, and the semiconductor material layer may be left in the recess by RIE in the vertical direction, so as to form a second sub-spacer 1027′. The second sub-spacer 1027′ defines the space for the gate stack along with the first sub-spacer 1027. An outer sidewall of the second sub-spacer 1027′ may be substantially coplanar with an outer sidewall of the first sub-spacer 1027 (as well as the sidewalls of the nanowires/nanosheets 1009 and 1013). An inner sidewall of the second sub-spacer 1027′ may be substantially flat (so as to define substantially the same gate lengths above and below the nanowires/nanosheets 1009 and 1013). The second sub-spacer 1027′ may include a material with substantially the same crystal structure as the nanowires/nanosheets 1009 and 1013, such as SiGe. Considering the etching selectivity, the Ge content of SiGe in the second sub-spacer 1027′ is higher than that in the gate defining layers 1007, 1011, 1015 and 1021, for example, the atomic percentage of Ge is in a range of about 20% to 60%. As shown in FIGS. 9(a) and 9(c), on opposite sides in the first direction, crystal growth surfaces (the outer sidewall of the second sub-spacer 1027′ and the sidewalls of the nanowires/nanosheets 1009 and 1013) that extend substantially continuous and have substantially consistent crystal structures may be formed, rather than some discrete growth points as shown in FIG. 22(b).

Here, the second sub-spacer 1027′ which is conductive to crystal growth is formed by epitaxial growing the semiconductor material. The nanowires/nanosheets 1009 and 1013, and the gate defining layers 1007, 1011 and 1015 (as well as the isolation portion defining layer 1003 and the etch stop layer 1005) are semiconductor materials and may be formed by epitaxial growth, which helps to form a substantially consistent crystal structure.

According to another embodiment of the present disclosure, a non-semiconductor material such as a dielectric material may be used to form the second sub-spacer 1027′. Unlike the dielectric material used for an existing spacer such as an oxide, a nitride, a nitrogen oxide, etc., the dielectric material used for the second sub-spacer 1027′ here may have substantially the same crystal structure as the nanowires/nanosheets 1009 and 1013, and the recess may be filled with the dielectric material by epitaxial growth or deposition followed by RIE. The second sub-spacer 1027′ may form a eutectic along with the nanowires/nanosheets 1009 and 1013, or the subsequently formed source/drain layer. For example, the second sub-spacer 1027′ may include a single crystal dielectric material that may match the lattices of the nanowires/nanosheets 1009 and 1013, such as an oxide or a nitride of strontium (Sr), titanium (Ti), lanthanum (La), aluminum (Al), neodymium (Nd), lutetium (Lu), gadolinium (Gd), or a combination thereof. For example, the second sub-spacer 1027′ may include at least one of SrTiO₃, LaAlO₃, NdAlO₃, GdAlO₃, or the like. According to the embodiment, a deviation between the lattice constant of the second sub-spacer 1027′ without strain and the lattice constants of the nanowires/nanosheets 1009 and 1013 without strain is within +2%. The description of crystal structure and lattice constant also applies to a case where the second sub-spacer 1027′ includes a semiconductor material.

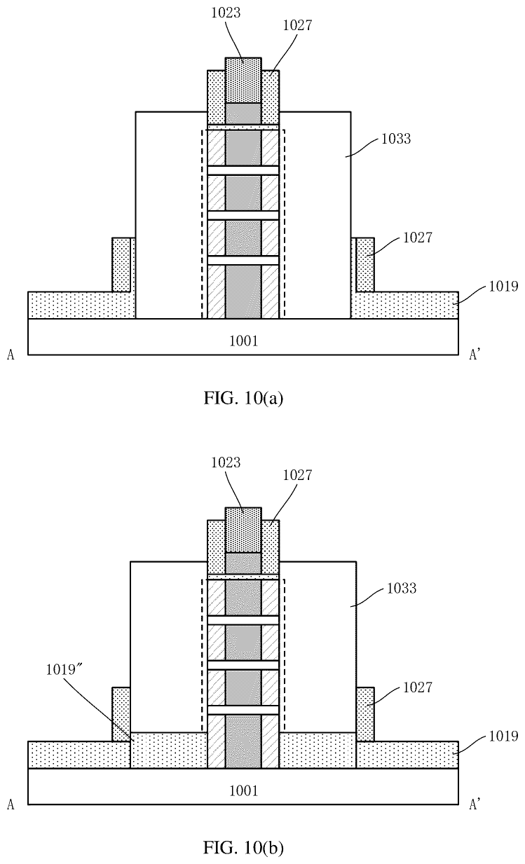

As shown in FIG. 10(a), the outer sidewall of the second sub-spacer 1027′ and the exposed sidewalls of the nanowires/nanosheets 1009 and 1013 (and the etch stop layer 1005) (as well as the exposed surface of the substrate 1001) may be used as seeds to form a source/drain layer 1033 by selective epitaxial growth, for example. As described above, the first sub-spacer 1027 may guide the growth of the source/drain layer 1033. The source/drain layer 1033 may be formed to adjoin all exposed sidewalls of the nanowires/nanosheets 1009 and 1013. The source/drain layer 1033 may include various suitable semiconductor materials. To enhance device performance, the source/drain layer 1033 may contain a semiconductor material with a lattice constant different from the nanowire/nanosheet so as to apply a stress to the nanowire/nanosheet in which the channel region will be formed. For example, for an n-type device, the source/drain layer 1033 may include Si: C (with a C atom percentage in a range of about 0.1% to 3%) to apply a tensile stress. For a p-type device, the source/drain layer 1033 may include SiGe (with a Ge atom percentage in a range of about 20% to 80%) to apply a compressive stress. In addition, the source/drain layer 1033 may be doped to a desired conductivity type (n-type doping for the n-type device and p-type doping for the p-type device), by in situ doping or ion implantation.

Due to the presence of the continuous extending and substantially consistent crystal growth surface shown in FIG. 9(c), the grown source/drain layer 1033 may have good crystal quality with almost no or fewer (compared to the situation shown in FIG. 23) crystal defects such as dislocations or interfaces. In addition, good crystal quality may also help improve the stress level when applying the stress.

In addition, as shown in FIG. 9(c), except for the crystal growth surface in the middle, the first sub-spacer 1027 is on two sides in the second direction. This may limit the growth range of the source/drain layer in the second direction, thereby avoiding unnecessary connection between respective source/drain layers of devices adjacent in the second direction (to reduce unnecessary etching steps).

In addition, considering the following spacer replacement process, in order to better provide an etching stop position (to avoid affecting the grown source/drain layer 1033) when removing the second sub-spacer 1027′ (as well as the first sub-spacer 1027), an etch stop layer may be provided on the sidewall of the second sub-spacer 1027′. For example, the second sub-spacer 1027′ includes SiGe and the source/drain layer 1033 also includes SiGe, a thin layer of Si (with a thickness in a range of about 2 nm to 5 nm, for example) may be formed on the crystal growth surface by selective epitaxial growth as the etch stop layer, as shown in the dashed box in FIG. 10(a). If the second sub-spacer 1027′ has high etching selectivity relative to other material layers, especially the source/drain layer 1033, such as including the dielectric material described above, then such etch stop layer may not be formed.

In an embodiment shown in FIG. 10(a), the source/drain layer grown from the sidewall of the nanowire/nanosheet adjoins the source/drain layer grown from the surface of the substrate 1001. This helps to dissipate heat or enhance the stress in the channel, thereby improving the device performance.

According to another embodiment of the present disclosure, as shown in FIG. 10(b), an isolation portion 1019″ such as STI may be formed on the substrate 1001 before growing the source/drain layer 1033, so as to electrically isolate the subsequently grown source/drain layer 1033 from the substrate 1001 and suppress the leakage current. For example, the isolation portion 1019″ may be formed by depositing an oxide, performing a planarization processing such as CMP on the deposited oxide, and etching back the planarized oxide.

Hereinafter, a situation shown in FIG. 10(a) will be mainly taken as an example for description, but such description also applies to a situation shown in FIG. 10(b).

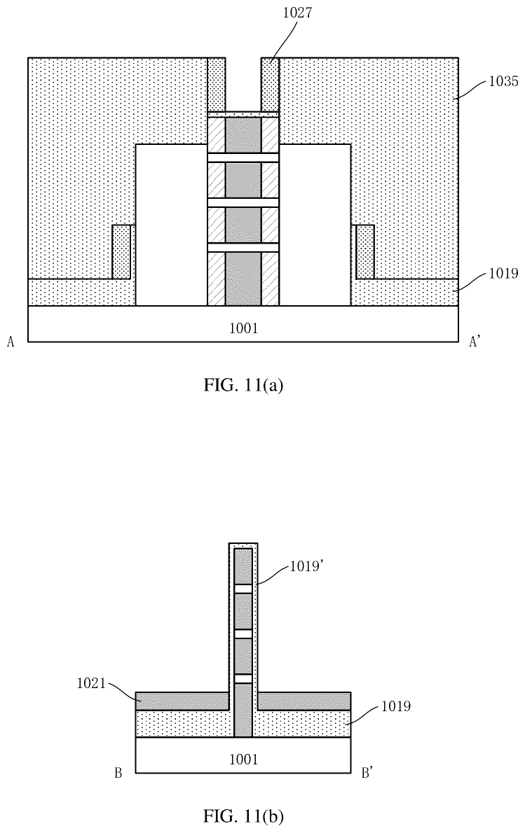

As shown in FIGS. 11(a) and 11(b), an interlayer dielectric layer 1035 may be formed on the substrate 1001. For example, the interlayer dielectric layer 1035 may be formed by depositing an oxide, performing a planarization processing such as CMP on the deposited oxide, and etching back the planarized oxide. The interlayer dielectric layer 1035 may expose the hard mask layer 1023, but cover the source/drain layer 1033. The interlayer dielectric layer 1035 exposes a region where the dummy gate is located and covers other regions, thereby facilitate performing the spacer replacement process and the gate replacement process subsequently.

Before forming the interlayer dielectric layer 1035, the source/drain layer 1033 may be optionally etched back according to a height of a top surface of the previously grown source/drain layer 1033, so as to avoid a short circuit caused by excessive growth of the source/drain layer 1033, for example.

Here, considering the formation of the isolation portion below the lowest gate defining layer 1007, the isolation portion defining layer 1003 may be processed, specifically, replaced with the isolation portion. In this way, a processing channel to the isolation portion defining layer 1003 may be formed.

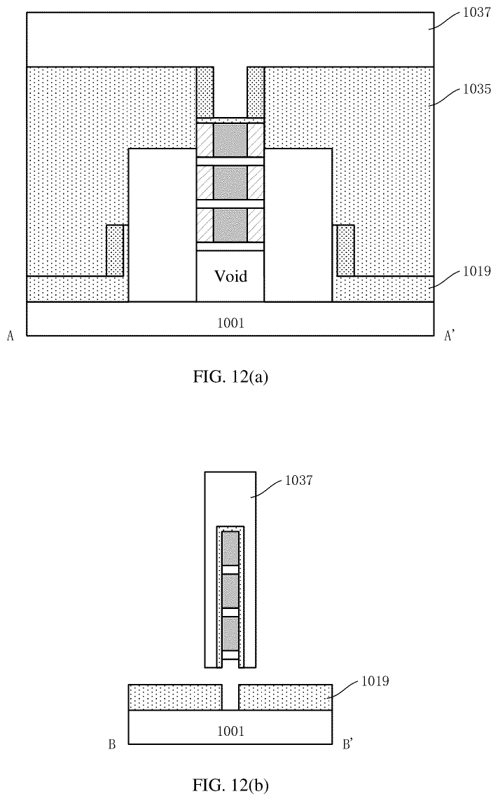

For example, the hard mask layer 1023 may be removed by selective etching to expose the gate defining layer 1021. By selective etching, the height of the gate defining layer 1021 may be reduced to a point where the top surface of the gate defining layer 1021 is lower than the top surface of the isolation portion defining layer 1003, but still maintains a certain thickness, so that the subsequently formed mask layer (see 1037 in FIGS. 12(a) and 12(b)) may shield all the gate defining layers 1007, 1011 and 1015 above the top surface of the isolation portion defining layer 1003, and expose the isolation portion defining layer 1003. For example, ALE may be used to control the etching depth well. Here, due to the presence of the etch stop layer 1019′, other gate defining layers 1007, 1011 and 1015 may not be affected.

Next, as shown in FIGS. 12(a) and 12(b), a mask layer, such as a photoresist 1037, may be formed on the gate defining layer 1021. The photoresist 1037 may be patterned as a strip extending along the extension direction of the nanowire/nanosheet by photolithography, and may shield the outer surfaces of the nanowire/nanosheet and gate defining layers 1007, 1011 and 1015 (with the etch stop layer 1019′ sandwiched therebetween). Due to the presence of the gate defining layer 1021, a part of the surface of the isolation portion defining layer 1003 is not shielded by the photoresist 1037. Afterwards, selective etching may be used to sequentially remove the gate defining layer 1021, a part of the etch stop layer 1019′ exposed due to the removal of the gate defining layer 1021, and the isolation portion defining layer 1003 exposed due to the removal of the part of the etch stop layer 1019′. Therefore, a void is formed under the etch stop layer 1005. As the isolation portion defining layer 1003 is defined by the same hard mask layer as the upper nanowires/nanosheets and gate defining layers, the isolation portion defining layer 1003 is aligned with the upper nanowires/nanosheets and gate defining layers in the vertical direction. Therefore, the void formed by the removal of the isolation portion defining layer 1003 may be self-aligned with the upper nanowires/nanosheets and gate defining layers. Afterwards, the photoresist 1037 may be removed.

Here, when etching the isolation portion defining layer 1003 of SiGe, the second sub-spacer 1027′ of SiGe (although their Ge concentrations are different) on the sidewall of the isolation portion defining layer 1003 may also be removed. The first sub-spacer 1027 may be substantially free from erosion, and thus may well define the space used for the gate stack. In this etching step, the second sub-spacer 1027′ may also be substantially unaffected or less affected, and replaced in the subsequent spacer replacement process.

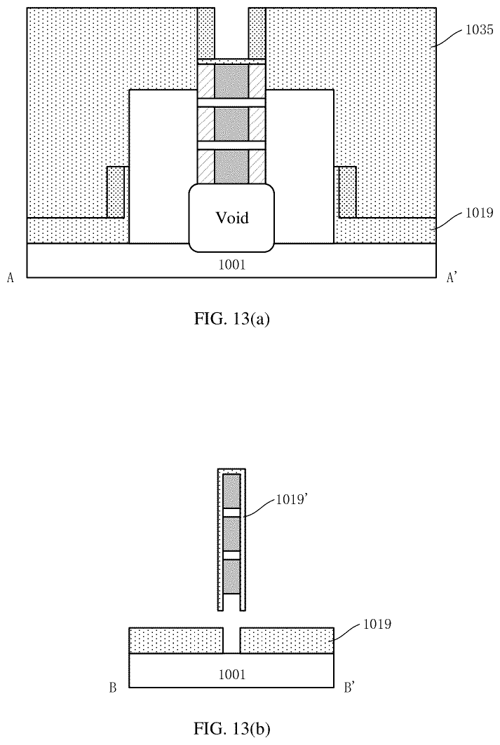

In this example, the etch stop layer 1005 is also a semiconductor material and is connected between opposite source/drain layers, which may lead to a leakage path. In this way, as shown in FIGS. 13(a) and 13(b), the etch stop layer 1005 may be removed by selective etching, such as wet etching using TMAH solution or ALE. In addition, in this example, both the etch stop layer 1005 and the substrate 1001 include silicon, and thus a part of the substrate 1001 may also be etched away. Accordingly, the void between the lowest gate defining layer 1007 and the substrate 1001 may be enlarged, but may still maintain substantial alignment with the upper nanowires/nanosheets and gate defining layers. And, FIG. 13(a) shows an expansion of the void towards two sides, for example due to the etching of the etch stop layer (please refer to a dashed box in FIG. 10(a)) as described above or the over-etching of the source/drain layer 1033.

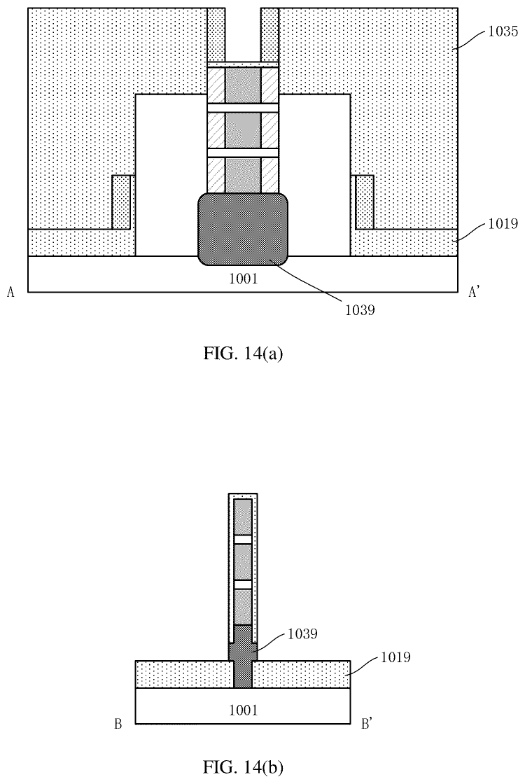

As shown in FIGS. 14(a) and 14(b), a dielectric material, such as a low k dielectric material, may be filled in the void thus formed to form an isolation portion 1039. Considering the etching selectivity (such as relative to the interlayer dielectric layer 1035, the STI 1019, the first sub-spacer 1027, the second sub-spacer 1027′, etc.), the isolation portion 1039 may include a nitrogen oxide (such as a silicon oxynitride). For example, the isolation portion 1039 may be formed by depositing sufficient nitrogen oxide on the substrate 1001 and etching back the deposited nitrogen oxide by RIE. The isolation portion 1039 thus formed may be self-aligned with the upper nanowires/nanosheets and gate defining layers. As shown in FIG. 14(b), the isolation portion 1039 adjoins the STI 1019 in the second direction.

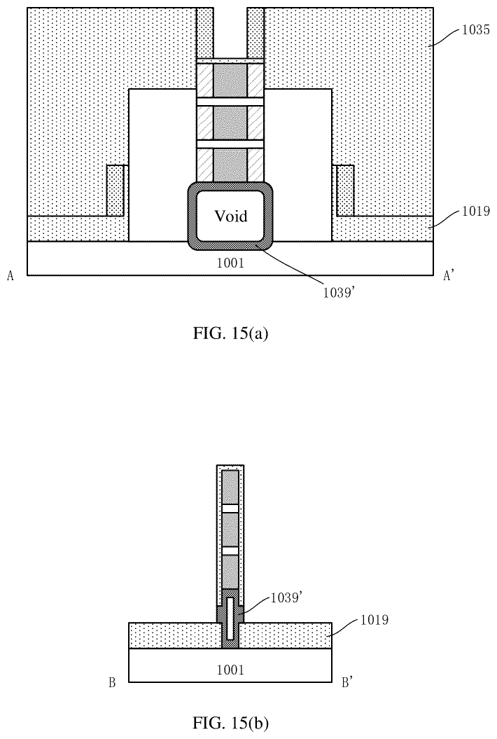

According to another embodiment, as shown in FIGS. 15(a) and 15(b), when depositing the dielectric material, the isolation portion 1039′ may have a hollow due to the limited space of the void described above. In this way, the dielectric constant of the isolation portion 1039′ may be further reduced.

Next, the spacer replacement process may be performed.

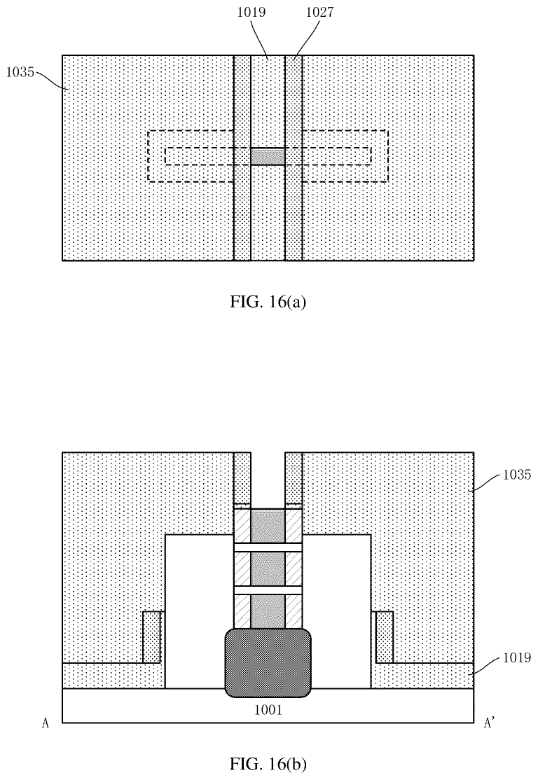

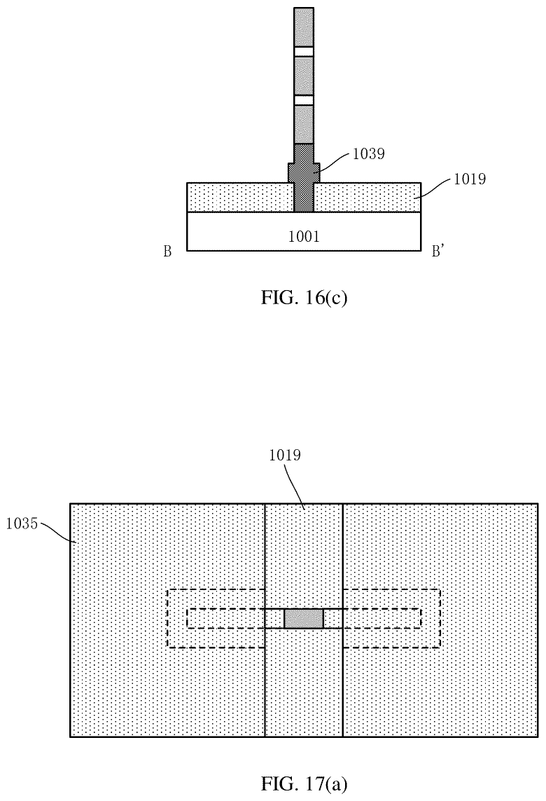

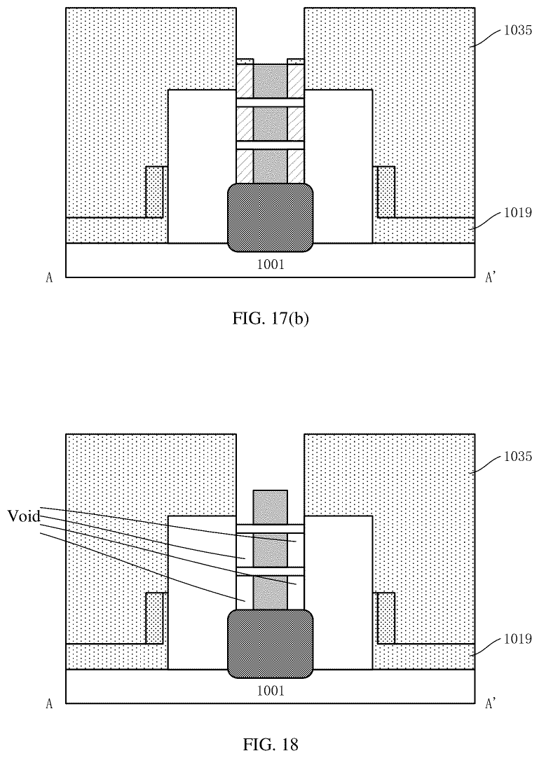

As shown in FIGS. 16(a), 16(b) and 16(c), the thin etch stop layer 1019′ may be removed by selective etching to expose the gate defining layer below. In the top view, for the sake of illustration convenience, a relatively protruding part (please refer to FIG. 16(c), where the isolation portion 1039 is relatively protruding on left and right sides) of the isolation portion 1039 is not shown. Then, as shown in FIGS. 17(a) and 17(b), the first sub-spacer 1027 may be removed by selective etching. Here, ALD may be used to achieve good etching control, so as to minimize erosion of the first sub-spacer 1027 below the interlayer dielectric layer 1035.

Next, as shown in FIG. 18, the residual etch stop layer 1019′ may be removed by selective etching, such as RIE, to expose the second sub-spacer 1027′ (the sidewall of the second sub-spacer 1027′ in the second direction). In a case where the gate defining layers 1007, 1011 and 1015, as well as the source/drain layer 1033 and the second sub-spacer 1027′ also include SiGe, they may have etching selectivity due to differences in Ge concentration (or Ge atom percentage), for example. Then, the second sub-spacer 1027′ may be removed by selective etching such as wet etching. In the presence of the etch stop layer (please refer to dashed boxes in FIGS. 10(a) and 10(b)) as described above, etching may be stopped at the etch stop layer. Accordingly, a space for the spacer is left between the gate defining layers 1007, 1011 and 1015, and the source/drain layer 1033.

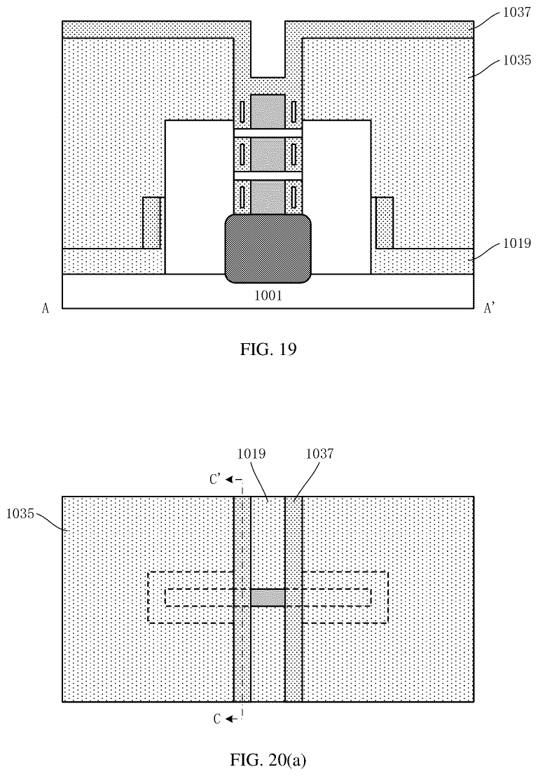

The spacer may be formed through the spacer formation process. For example, as shown in FIG. 19, a dielectric layer 1037 may be formed in a substantially conformal manner by deposition. Considering the etching selectivity (such as relative to the interlayer dielectric layer 1035 of oxide, the STI 1019 of oxide, and the isolation portion 1039 of nitrogen oxide), the dielectric layer 1037 may include nitride. The dielectric layer 1037 is filled into gaps between the gate defining layers 1007, 1011, 1015 and the source/drain layer 1033, so as to be self-aligned with each gate defining layer. These gaps are small, so when filling these gaps with the dielectric layer 1037, a seam or an interface or a surface may be formed inside. Due to such seam or interface or surface, the dielectric layer may be O-shaped or U-shaped locally (around the seam or interface or surface). Specifically, deposition may start from the surfaces, and material layers deposited on the surfaces approach each other as the deposition thickness increases. The seam or interface or surface may be formed between the surfaces of material layers that are close to each other (due to a limited space, they may not converge completely). Then, as shown in FIGS. 20(a), 20(b) and 20(c), selectively etching such as RIE in the vertical direction may be performed on the deposited dielectric layer 1037, so as to remove a part of the dielectric layer 1037 on the top surface of the interlayer dielectric layer 1035 and thus form a spacer, which is still indicated by 1037 here.

More specifically, the spacer 1037 may include a first part (which may correspond to the second sub-spacer 1027′ and possibly the part of the first sub-spacer 1027 overlapping with the nanowires/nanosheets 1009 and 1013 in the vertical direction, as shown in FIG. 9(c)) that overlaps with the nanowires/nanosheets 1009 and 1013 in the vertical direction, as well as second and third parts (which may correspond to parts of the first sub-spacer 1027 on opposite sides of the stack of semiconductor layers in the second direction, as shown in FIG. 9(c)) located on the opposite sides of the first part in the second direction and extending from the first part. During the formation, as a narrow space defined by the gate defining layer, the source/drain layer, and the nanowire/nanosheet needs to be filled with the first part of the spacer 1027, a seam or an air gap may be easily formed inside, thereby reducing the dielectric constant of the spacer. In the narrow space, the filling starts from the sidewall of the narrow space. In this way, the material layer of the first part of the formed spacer 1027 may be in a shape of the sidewall along the narrow space. For example, the first part of the spacer 1027 may have a first part along the surface of the nanowire/nanosheet, a second part along the sidewall of the source/drain layer facing the dummy gate, and a third part (for example, in a U-shape) along the sidewall of the dummy gate facing the source/drain layer, And optionally, the first part of the spacer 1027 may further have a fourth part (for example, in an O-shape) opposite to the first part (such as along surfaces of adjacent nanowires/nanosheets or along the surface of the isolation portion 1039) and connecting the second part and the third part. Regardless of the anisotropy of filling dielectric layer, the film thickness starting from each sidewall may be substantially the same, i.e., each of the first, second, and third parts (as well as the fourth part) may have a substantially uniform film thickness (in the same cross-section perpendicular to the second direction). In addition, the second and third parts of the spacer 1027 do not have the limitation caused by the narrow space, so there are substantially no seams in the second and third parts of the spacer 1027.

It should be pointed out that, although the voids are shown as rectangles in FIG. 20(c), they may be in other shapes, such as an olive-shape (with small seams on two sides and large seams in the middle).

Next, the gate replacement process may be performed.

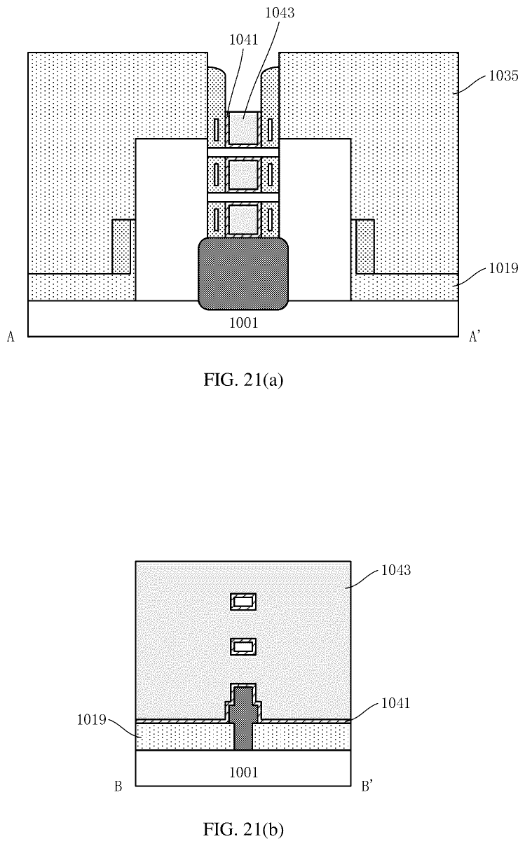

For example, as shown in FIGS. 21(a) and 21(b), the gate defining layer may be removed by selective etching. Then, a gate trench (corresponding to the space originally occupied by each gate defining layer) is formed on an inner side of the spacer 1037 and above the STI 1019 and the isolation portion 1039. In the gate trench formed in this way, a gate dielectric layer 1041 and a gate electrode 1043 may be sequentially formed to obtain the final gate stack. For example, the gate dielectric layer 1041 may include a high k gate dielectric such as HfO₂, with a thickness in a range of about 2 nm to 10 nm. The gate electrode 1043 may include a work function adjustment layer such as TiN, TiAlN, TaN, etc., as well as a gate conductor layer such as W, Co, Ru, etc. Before forming the high k gate dielectric, an interface layer may also be formed, such as an oxide formed through an oxidation process or deposition such as atomic layer deposition (ALD), with a thickness in a range of about 0.3 nm to 2 nm.

As shown in FIGS. 21(a) and 21(b), the nanowire/nanosheet device according to embodiments may include the nanowires/nanosheets 1009 and 1013 (which may be fewer or more in number) spaced apart from the substrate 1001, as well as the gate stack surrounding the nanowires/nanosheets 1009 and 1013. The gate stack includes the gate dielectric layer 1041 and the gate electrode 1043.

The spacer 1037 is formed on the sidewall of the gate stack. Inner sidewalls of the spacer 1037 adjoining the gate stack may be substantially coplanar in the vertical direction, so as to provide the same gate length. In addition, the outer sidewalls of the spacer 1037 may also be coplanar in the vertical direction and may be coplanar with the sidewalls of the nanowires/nanosheets 1009 and 1013. As described above, the spacer 1037 may have the seam or interface or surface, and thus may be locally O-shaped or U-shaped.

The nanowire/nanosheet device may also include the isolation portion 1039. As described above, the isolation portion 1039 may be self-aligned with the gate stack or nanosheets 1009 and 1013. The spacer 1037 may not be formed on the sidewall of the isolation portion 1039.

In above embodiments, in order to improve the growth quality of the source/drain layer, the first sub-spacer 1027 and the second sub-spacer 1027′ are formed separately. However, the present disclosure is not limited to this. For example, a dummy spacer may be formed at one time as described above in conjunction with FIGS. 22(a) and 22(b). After growing the source/drain layer, the spacer replacement process may also be performed. When forming the spacer, due to the presence of the source/drain layer and the dummy gate, there is also a limited space, which may lead to a seam in the spacer, so that the dielectric constant of the spacer is reduced. Therefore, although the growth quality of the source/drain layer may not be improved, performance improvement is still achieved.

According to an embodiment of the present disclosure, the dummy gate may also be used to form a self-aligned isolation portion, such as shallow trench isolation (STI).

FIGS. 24(a) to 31 show schematic diagrams of some stages in a process of manufacturing a nanowire/nanosheet device according to another embodiment of the present disclosure. The following mainly describes the differences between this embodiment and the above embodiments. For other processes not described in detail, please refer to the above embodiments.

As described above in conjunction with FIGS. 1 to 4(b), a stack of semiconductor layers may be provided on the substrate 1001, and may be patterned as a preparatory nanowire/nanosheet. An isolation portion 1019 may be formed around the preparatory nanowire/nanosheet, and an etch stop layer 1019′ may be formed on the surface of the isolation portion 1019.

As shown in FIGS. 24(a) and 24(b), the dummy gate may be patterned as described above in conjunction with FIGS. 5(a) and 5(b). Here, the photoresist 1025 is patterned as a plurality of (e.g., three) strips spaced (which may be substantially equidistant) in the first direction and extending along the second direction.

Next, the process may be performed according to above embodiments.

For example, as shown in FIGS. 25(a) to 25(d), a first sub-spacer 1027 may be formed on the sidewall of the gate defining layer 1021 of strip as described above in conjunction with FIGS. 6(a) and 6(b). The first sub-spacer 1027 may also be formed on the (bottom) sidewall of the stack of semiconductor layers to guide the growth of the source/drain layer. Then, as described above in conjunction with FIGS. 7 to 9(c), a second sub-spacer 1027′ may be formed, as shown in FIGS. 26(a) to 26(d). Similarly, as shown in FIG. 26(d), crystal growth surfaces (the outer sidewall of the second sub-spacer 1027′ and the sidewalls of the nanowires/nanosheets 1009 and 1013) that extend substantially continuous and have substantially identical crystal structures may be formed on opposite sides in the first direction. Afterwards, the source/drain layer 1033 may be grown as described above in combination with FIGS. 10(a) and 10(b). FIG. 27 schematically shows a situation similar to FIG. 10(a), but an isolation portion may also be formed under the source/drain layer as described in conjunction with FIG. 10(b).

Here, the dummy gate may be used to fabricate the self-aligned isolation portion.

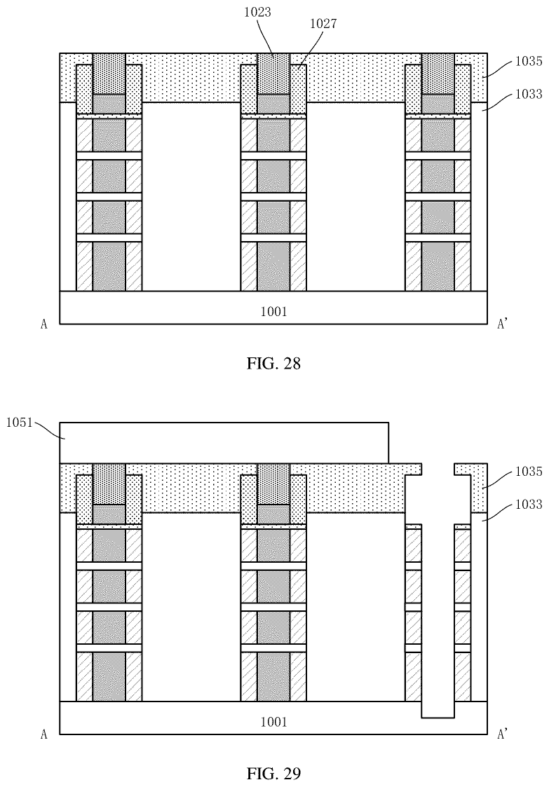

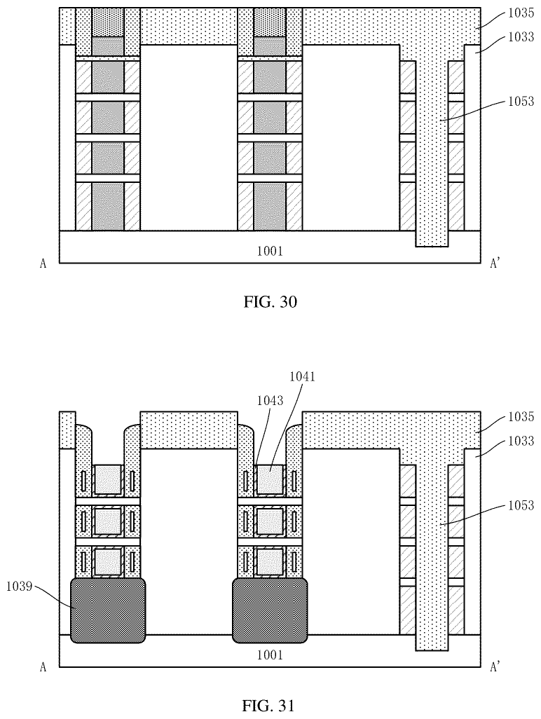

For example, as shown in FIG. 28, an interlayer dielectric layer 1035 may be formed on the substrate 1001. The interlayer dielectric layer 1035 may expose the hard mask layer 1023. As shown in FIG. 29, a photoresist 1051 may be used to shield a device region and expose a region where the isolation portion needs to be formed (in this example, a region where the rightmost dummy gate is located in FIG. 29). In the region exposed by the photoresist 1051, the hard mask layer 1023, gate defining layers 1021, 1015, 1011 and 1017, nanowires/nanosheets 1013 and 1019, as well as the isolation portion defining layer 1003 (as well as the etch stop layers 1019′ and 1005) may be removed by selective etching such as RIE. Here, the first sub-spacer 1027 may also be removed. Therefore, a trench corresponding to the dummy gate is formed. Afterwards, the photoresist 1051 may be removed. As shown in FIG. 30, the trench thus formed may be filled with a dielectric such as an oxide to form an isolation portion 1053. Here, as both the isolation portion 1053 and the interlayer dielectric layer 1035 contain oxides, an interface between the isolation portion 1053 and the interlayer dielectric layer 1035 is not shown. However, as the isolation portion 1053 and the interlayer dielectric layer 1035 are formed separately, it is possible to observe the interface between the isolation portion 1053 and the interlayer dielectric layer 1035. Alternatively, the isolation portion 1053 has a second sub-spacer 1027′, a nanowire/nanosheet residue, etc. on the sidewall, so as to define the sidewall of the isolation portion 1053. Alternatively, even if the second sub-spacer 1027′ and the nanowire/nanosheet residue on the sidewall of the trench are difficult to observe because they are almost removed due to etching control in the process of forming the trench, the sidewall of the isolation portion 1053 may still be defined due to the presence of the source/drain layers on two sides of the isolation portion 1053.

Next, the process may be performed according to above embodiments, such as performing the spacer replacement process and the gate replacement process. When performing the spacer replacement process, the region where the isolation portion 1053 is located is shielded by the isolation portion 1053, so the second sub-spacer 1057′ may not be replaced. Accordingly, the nanowire/nanosheet device shown in FIG. 31 may be obtained.

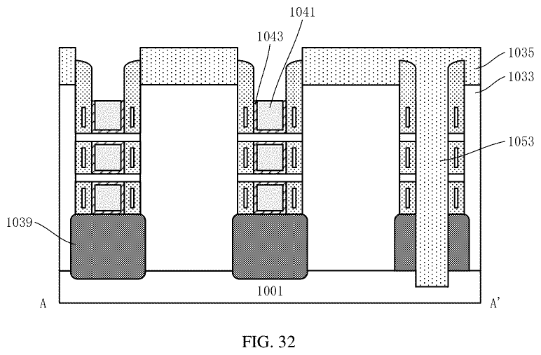

In this example, the isolation portion 1053 is formed, and then the spacer replacement process and the gate replacement process are performed. However, the present disclosure is not limited to this. For example, the spacer replacement process and the gate replacement process may be performed as described in above embodiments, and then the isolation portion 1053 may be formed (except that the gate defining layer has been replaced with the gate stack when etching the trench). Accordingly, the nanowire/nanosheet device shown in FIG. 32 may be obtained.

In the above embodiment, a single material layer (such as an oxide) is used as an example to describe the spacer 1037. However, the present disclosure is not limited to this. For example, the spacer 1037 may include a stack of multiple layers (such as a nitride layer and an oxide layer). For example, the layers in the stack may be sequentially deposited by ALD.

The nanowire/nanosheet device according to embodiments of the present disclosure may be applied to various electronic apparatuses. For example, an integrated circuit (IC) may be formed based on such nanowire/nanosheet devices, and an electronic apparatus may be constructed in this way. Therefore, the present disclosure further provides an electronic apparatus including the nanowire/nanosheet device described above. The electronic apparatus may further include components such as a display screen cooperating with the integrated circuit and a wireless transceiver cooperating with the integrated circuit. The electronic apparatus may include, for example, a smart phone, a personal computer, a tablet computer, a wearable intelligence apparatus, an artificial intelligence apparatus, and a mobile power supply.

According to embodiments of the present disclosure, a method of manufacturing a system on chip (SoC) is further provided, which may include the methods described above. Specifically, a variety of devices may be integrated on the chip, at least some of which are manufactured according to the methods of the present disclosure.

In the above descriptions, technical details such as patterning and etching of each layer have not been described in detail. However, those skilled in the art should understand that various technical means may be used to form layers, regions, etc. of desired shapes. In addition, in order to form the same structure, those skilled in the art may further design a method that is not completely the same as the method described above. In addition, although the various embodiments are described above separately, this does not mean that the measures in the various embodiments may not be advantageously used in combination.

Embodiments of the present disclosure have been described above. However, these embodiments are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should all fall within the scope of the present disclosure.

1. A nanowire/nanosheet device, comprising:
a substrate;
a nanowire/nanosheet spaced apart from a surface of the substrate and extending in a first direction;
a source/drain layer located at opposite ends of the nanowire/nanosheet in the first direction and adjoining the nanowire/nanosheet;
a gate stack extending in a second direction intersecting with the first direction to surround the nanowire/nanosheet; and
a first spacer provided on a sidewall of the gate stack,
wherein the first spacer comprises a continuously extending material layer, the continuously extending material layer has a first part along a surface of the nanowire/nanosheet, a second part along a sidewall of the source/drain layer facing the gate stack, and a third part along a sidewall of the gate stack facing the source/drain layer, and the second part and the third part have a seam or an interface therebetween.

2. The nanowire/nanosheet device according to claim 1, wherein the continuously extending material layer further has a fourth part opposite to the first part and connecting the second part and the third part.

3. The nanowire/nanosheet device according to claim 1, wherein the first part, the second part, and the third part have a substantially uniform film thickness.

4. The nanowire/nanosheet device according to claim 2, wherein the first part, the second part, the third part, and the fourth part have a substantially uniform film thickness.

5. The nanowire/nanosheet device according to claim 1, wherein the seam is an air gap.

6. The nanowire/nanosheet device according to claim 1, wherein the source/drain layer has fewer growth defects compared to a case where the source/drain layer is grown solely by using the ends of the nanowire/nanosheet in the first direction as a seed.

7. The nanowire/nanosheet device according to claim 6, wherein the source/drain layer substantially does not have a growth defect.

8. The nanowire/nanosheet device according to any claim 1, wherein a plurality of nanowires/nanosheets are provided, the plurality of nanowires/nanosheets extend substantially parallel to each other in the first direction and are substantially aligned in the vertical direction, and
wherein the source/drain layer has a substantially identical and continuous crystal surface between at least one pair of adjacent nanowires/nanosheets among the plurality of nanowires/nanosheets.

9. The nanowire/nanosheet device according to claim 8, wherein a crystal structure of the source/drain layer is a crystal grown from a vertically continuous extending and substantially identical crystal surface between the plurality of nanowires/nanosheets.

10. The nanowire/nanosheet device according to claim 1, further comprising:
an isolation portion between the gate stack and the substrate,
wherein the isolation portion is self-aligned with the gate stack.

11. The nanowire/nanosheet device according to claim 10, wherein the first spacer is not formed between the isolation portion and the source/drain layer.

12. The nanowire/nanosheet device according to claim 10, wherein the isolation portion is self-aligned with a plurality of nanowires/nanosheets.

13. The nanowire/nanosheet device according to claim 10, wherein the isolation portion has a hollow.

14. The nanowire/nanosheet device according to claim 1, further comprising:
a further spacer on the substrate that adjoins the first spacer, wherein the further spacer defines a lower part of the source/drain layer.

15. The nanowire/nanosheet device according to claim 14, wherein a space defined by the further spacer is aligned with the nanowire/nanosheet in the first direction.

16. The nanowire/nanosheet device according to claim 1, further comprising:
a semiconductor layer between the first spacer and the source/drain layer, wherein the semiconductor layer has an etching selectivity relative to the source/drain layer.

17. The nanowire/nanosheet device according to claim 10, further comprising:
a further isolation portion provided on a side of at least one source/drain layer facing away from the nanowire/nanosheet in the first direction, wherein a bottom surface of the further isolation portion is lower than a top surface of the isolation portion,
wherein the further isolation portion extends in the second direction.

18. The nanowire/nanosheet device according to claim 17, further comprising:
a second spacer provided on a sidewall of the further isolation portion.

19. The nanowire/nanosheet device according to claim 18, wherein the first spacer comprises a first part above the nanowire/nanosheet and a second part under the nanowire/nanosheet, and the second spacer comprises a first part substantially at the same height as the first part of the first spacer and a second part substantially at the same height as the second part of the first spacer.

20. The nanowire/nanosheet device according to claim 19, further comprising:
a nanowire/nanosheet residue located between the first and second parts of the second spacer and adjoining the at least one source/drain layer.

21. The nanowire/nanosheet device according to claim 20, wherein the nanowire/nanosheet residue is substantially coplanar with the nanowire/nanosheet.

22. The nanowire/nanosheet device according to claim 1, wherein the first part, the second part, and the third part are in a U-shape.

23. The nanowire/nanosheet device according to claim 2, wherein the first part, the second part, the third part, and the fourth part are in an O-shape.

24. The nanowire/nanosheet device according to claim 1, wherein the first spacer comprises a stack of multiple layers.

25. A method of manufacturing a nanowire/nanosheet device, comprising:
providing, on a substrate, a nanowire/nanosheet spaced apart from a surface of the substrate and extending in a first direction;
forming, on the substrate, a dummy gate extending in a second direction intersecting with the first direction and surrounding the nanowire/nanosheet, wherein a first spacer is formed on a sidewall of the dummy gate;
growing a source/drain layer on opposite ends of the nanowire/nanosheet in the first direction;
replacing the first spacer with a second spacer in a presence of the source/drain layer and at least a part of the dummy gate; and
forming a gate stack on an inner side of the second spacer,
wherein the second spacer comprises a continuously extending material layer, the continuously extending material layer has a first part along a surface of the nanowire/nanosheet, a second part along a sidewall of the source/drain layer facing the gate stack, and a third part along a sidewall of the gate stack facing the source/drain layer, and the second part and the third part have a seam or an interface therebetween.

26. The method according to claim 25, wherein the continuously extending material layer further has a fourth part opposite to the first part and connecting the second part and the third part.

27. The method according to claim 25, wherein the first part, the second part, and the third part have a substantially uniform film thickness.

28. The method according to claim 26, wherein the first part, the second part, the third part, and the fourth part have a substantially uniform film thickness.

29. The method according to claims 25 to 28, wherein the first spacer has a crystal structure substantially identical to the nanowire/nanosheet at least in a region of the first spacer adjacent to the nanowire/nanosheet.

30. The method according to claim 29, wherein a plurality of nanowires/nanosheets are provided on the substrate, and the plurality of nanowires/nanosheets are spaced apart from each other in a vertical direction, and
wherein the region comprises a region that overlaps with the plurality of nanowires/nanosheets in the vertical direction.

31. The method according to claim 29, wherein the first spacer comprises a semiconductor material or a dielectric material in the region.

32. The method according to claim 31, wherein the dielectric material comprises an oxide or a nitride of strontium (Sr), titanium (Ti), lanthanum (La), aluminum (Al), neodymium (Nd), lutetium (Lu), gadolinium (Gd), or a combination thereof.

33. The method according to claim 32, wherein the dielectric material comprises at least one of SrTiO₃, LaAlO₃, NdAlO₃, or GdAlO₃.

34. The method according to claim 25,
wherein providing the nanowire/nanosheet comprises:
forming an isolation portion defining layer on the substrate;
forming, on the isolation portion defining layer, a stack of a first gate defining layer, a nanowire/nanosheet defining layer, and a second gate defining layer;
patterning the stack and the isolation portion defining layer as a preparatory nanowire/nanosheet extending in the first direction;
forming a third gate defining layer on the substrate to cover the stack and the isolation portion defining layer;
patterning the third gate defining layer as a strip extending in the second direction;
forming a first sub-spacer on a sidewall of the strip-shaped third gate defining layer;
patterning the stack and the isolation portion defining layer into a wire or sheet shape by using the strip-shaped third gate defining layer and the first sub-spacer as a mask, wherein the nanowire/nanosheet defining layer patterned into the wire or sheet shape forms the nanowire/nanosheet,
wherein forming the dummy gate comprises:
selective etching the first gate defining layer and the second gate defining layer, so that sidewalls of the first gate defining layer and the second gate defining layer are inward recessed relative to a sidewall of the nanowire/nanosheet to form a recess, wherein the first gate defining layer, the second gate defining layer, and the third gate defining layer form the dummy gate together,
wherein the method further comprises:
growing, in the recess, a second sub-spacer by using the first gate defining layer and the second gate defining layer as a seed, wherein the first sub-spacer and the second sub-spacer form the first spacer together,
wherein the first spacer is replaced with the second spacer in a presence of the first gate defining layer, the second gate defining layer, and the source/drain layer.

35. The method according to claim 34, wherein the first sub-spacer is further formed on a sidewall of the stack.

36. The method according to claim 34, further comprising:
forming an etch stop layer on the isolation portion defining layer, wherein the stack is formed on the etch stop layer,
wherein the method further comprises: after growing the source/drain layer,
removing, by selective etching, the isolation portion defining layer from opposite sides of the nanowire/nanosheet in the second direction;
removing the etch stop layer by selective etching; and
filling a space formed by a removal of the isolation portion defining layer and the etch stop layer with a dielectric material, so as to form an isolation portion.

37. The method according to claim 36, wherein the isolation portion has a hollow.

38. The method according to claim 34, wherein replacing the first spacer with the second spacer comprises:
removing the third gate defining layer;
removing the first sub-spacer to expose an end of the second sub-spacer in the second direction;
removing the second sub-spacer; and
forming the second spacer, wherein s space originally occupied by the second sub-spacer is filled with the second spacer.

39. The method according to claim 34, wherein the strip comprises two strips, and the method further comprises:
forming an isolation portion at one of the two strips after growing the source/drain layer, wherein the isolation portion is self-aligned with the second spacer and passes through the nanowire/nanosheet.

40. An electronic apparatus, comprising the nanowire/nanosheet device according to claim 1.

41. The electronic apparatus according to claim 40, wherein the electronic apparatus comprises: a smart phone, a computer, a tablet computer, a wearable intelligence apparatus, an artificial intelligence apparatus, and a mobile power supply.
